(19) United States
(12) Patent Application Publication
(10) Pub. No.: US 2024/0309510 A1
(43) Pub. Date: Sep. 19, 2024

(54) METHOD FOR IN-SITU ETCHING DIAMOND

(71) Applicant: YANSHAN UNIVERSITY, Qinhuangdao City (CN)

(72) Inventors: Liqiang ZHANG, Qinhuangdao City (CN); Yunna GUO, Qinhuangdao City (CN)

(21) Appl. No.: 18/675,284

(22) Filed: May 28, 2024

Related U.S. Application Data
(63) Continuation of application No. PCT/CN2023/098513, filed on Jun. 6, 2023.

(30) Foreign Application Priority Data
Jun. 15, 2022 (CN) 202210672789.X

(51) Int. Cl. C23C 16/56; C23C 16/27

(52) U.S. Cl. CPC C23C 16/56; C23C 16/27

(57) ABSTRACT

A method for in-situ etching diamond is provided, relating to the technical field of diamond etching. According to the application, the diamond is etched by using the convergent electron beam in an atmosphere of reaction gas.

### CROSS-REFERENCE TO RELATED APPLICATIONS

This application is a continuation of PCT/CN2023/098513, filed on Jun. 6, 2023, and claims priority of Chinese Patent Application No. 202210672789. X, filed on Jun. 15, 2022, the entire contents of which are incorporated herein by reference.

### TECHNICAL FIELD

The application relates to the technical field of diamond etching, and in particular to a method for in-situ etching diamond.

### BACKGROUND

Diamond is the hardest substance in nature, with the advantages of good wear resistance, strong thermal conductivity and good chemical stability. The diamond is widely applied in processing machine tools, photoelectric materials, biomedicine and high-precision semiconductors.

Diamond etching is applicable in manufacturing quantum information devices, biomedical carriers, electrode materials, catalytic carriers, etc. However, there is few researches on diamond etching technology at present, and diamond surface etching technology is extremely important for improving diamond surface properties and expanding diamond applications. At present, the main diamond processing methods are laser cutting and plasma etching, which generally have the disadvantages of high cost, strict conditions, complex technology and low processing precision. Therefore, it is urgent to solve a problem of how to reduce the processing cost on the basis of improving the processing precision and processing speed of diamond in this field.

### SUMMARY

An objective of the present application is to provide a method for in-situ etching diamond, so as to solve problems existing in the prior art and realize high-precision and high-efficiency directional etching of diamond.

In order to achieve the above objectives, the present application provides a following scheme.

The application provides a method for in-situ etching diamond, which includes following step: etching diamond by using a convergent electron beam in an atmosphere of reaction gas. The reaction condition is room temperature, specifically 25° C. Firstly, a prepared nano-diamond is loaded into an Environmental Transmission Electron Microscope (ETEM) by a specimen holder, and the reaction gas is introduced and a portion to be etched is subjected to a high magnification, and then the diamond is directionally etched by the convergent electron beam.

Optionally, the reaction gas is one of O₂, CO₂, CO, H₂O or H₂.

Optionally, the reaction gas is CO₂.

Optionally, the reaction gas is a mixed reaction gas of O₂ and CO₂ in any ratio.

Optionally, the reaction gas is a mixed reaction gas of CO₂ and H₂ in any ratio.

Optionally, the reaction gas is a mixed reaction gas of CO₂, O₂ and a small amount of water vapor.

Optionally, a pressure of the atmosphere of reaction gas is 0.01-10 mbar.

Optionally, after reacting, a vacuum degree between samples is higher than 10⁻⁷ mbar.

Under the same conditions, as an amount of reaction gas increases, the etching speed is also accelerated. In the application, 10 mbar CO₂ is selected, so that a larger etching speed is ensured.

Optionally, a Dose rate value of the convergent electron beam is 5000 e/nm²s to 2×10⁵ e/nm²s. The Dose value of electron beam is related to the magnification. The greater the Dose value, the stronger the light intensity and the faster the etching speed.

At present, the methods for etching diamond are laser cutting and plasma etching. The laser etching achieves etching effect through ablation and photochemical action. The diamond surface absorbs a lot of energy delivered by laser, the temperature of diamond surface rises sharply, and the uneven heating leads to rough processing section. At present, the most advanced ultraviolet cutting may reach the processing precision of 500 nm. Plasma etching is a process in which gas molecules are activated into charged particles by voltage, the charged particles come into contact with atoms in the surface layer to produce a chemical reaction and gaseous products leave the surface layer to cause etching. Therefore, the entire sample to be etched is in plasma atmosphere, so it is impossible to perform fine directional etching proposed by the present disclosure on the sample.

The application uses the synergistic effect of reaction gas and electron beam to process diamond. The reaction gas is quickly activated under the condition of electron beam irradiation, and a rapid etching reaction is realized. A size of the electron beam spot determines the etching precision, the diameter of the convergent electron beam spot does not exceed 5 nm, the processing precision is much higher than that of laser processing, the processing technology is simple, the cost is low, directional etching is performed, and the processed diamond sample is clean and pollution-free, and no further treatment is needed, so that a lot of time and resources are saved, and the processing technology is applicable in high-efficiency directional processing of diamonds. The etching speed of diamond is different in different atmospheres. In CO₂ atmosphere, the etching efficiency of diamond is the highest, and the environment after etching is in a high vacuum state (the vacuum degree is higher than 10⁻⁷ mbar), so the etched waste is quickly pumped away, which further ensures the surface of the etched area to be clean.

The application discloses the following technical effects.

According to the application, the diamond is etched by using the convergent electron beam in the atmosphere of reaction gas, so that the method has the characteristics of high processing precision, simple process, low cost and high efficiency, and the directional etching of the diamond is realized; and the processed diamond sample is clean and pollution-free, and no further treatment is needed, so that a lot of time and resources is saved.

### BRIEF DESCRIPTION OF THE DRAWINGS

In order to explain the embodiments of the present application or the technical scheme in the prior art more clearly, the drawings needed in the embodiments will be briefly introduced below. Obviously, the drawings described below are only some embodiments of the present application, and other drawings may be obtained according to these drawings without creative work for ordinary people in the field.

FIG. 1 is a schematic diagram of in-situ etching diamond according to the present application.

FIG. 2A shows a diamond nanosheet before etching in Embodiment 1.

FIG. 2B shows diffracting diamond <112> direction in Embodiment 1.

FIG. 2C shows the diamond nanosheet after etching in Embodiment 1.

FIG. 3A is a diamond nanosheet before etching in Embodiment 2.

FIG. 3B shows diffracting diamond <110> direction in Embodiment 2.

FIG. 3C shows the diamond nanosheet after etching in Embodiment 2.

FIG. 4A is the diamond nanosheet before etching in Embodiment 3.

FIG. 4B shows diffracting diamond <110> direction in Embodiment 3.

FIG. 4C shows the diamond nanosheet after etching in Embodiment 3.

### DETAILED DESCRIPTION OF THE EMBODIMENTS

A number of exemplary embodiments of the present application will now be described in detail, and this detailed description should not be considered as a limitation of the present application, but should be understood as a more detailed description of certain aspects, characteristics and embodiments of the present application.

It should be understood that the terminology described in the present application is only for describing specific embodiments and is not used to limit the present application. In addition, for the numerical range in the present application, it should be understood that each intermediate value between the upper limit and the lower limit of the range is also specifically disclosed. The intermediate value within any stated value or stated range and every smaller range between any other stated value or intermediate value within the stated range are also included in the present application. The upper and lower limits of these smaller ranges may be independently included or excluded from the range.

Unless otherwise specified, all technical and scientific terms used herein have the same meaning as commonly understood by one of ordinary skill in the art to which this application relates. Although the present application only describes the preferred methods and materials, any methods and materials similar or equivalent to those described herein may also be used in the practice or testing of the present application. All documents mentioned in this specification are incorporated by reference to disclose and describe methods and/or materials related to the documents. In case of conflict with any incorporated document, the contents of this specification shall prevail.

It is obvious to those skilled in the art that many improvements and changes may be made to the specific embodiments of the present application without departing from the scope or spirit of the present application. Other embodiments are apparent to the skilled person from the description of the application. The description and embodiments of the present application are exemplary only.

The terms “comprising”, “including”, “having” and “containing” used in this article are all open terms, which means including but not limited to.

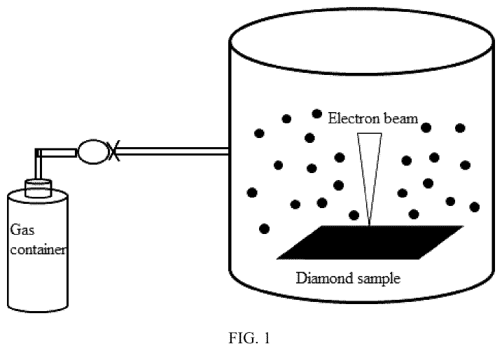

FIG. 1 is a schematic diagram of in-situ etching diamond according to the present application.

The diamond sheet in the embodiments of the application is made of a diamond block, and is specifically prepared by chemical vapor deposition (CVD) (molybdenum matrix).

### Embodiment 1

A diamond sheet obtained by CVD is made into diamond nanosheet, and then the diamond nanosheet is dipped with a 200-mesh copper mesh, and a specimen holder loaded with the copper mesh is put into the Environmental Transmission Electron Microscope (ETEM), and CO₂ reaction gas (the introduced amount is 10 mbar) is introduced, after that the electron beam is converged to a minimum spot (the diameter is less than 1 nm) and irradiated on the surface of the diamond to be etched, where the Dose value is 20,000 e/nm²s, and the spot is moved by rotating a roller to directionally etch diamond. It takes 25 seconds for diamond to appear a hole first, and 300 nm may be etched in one minute.

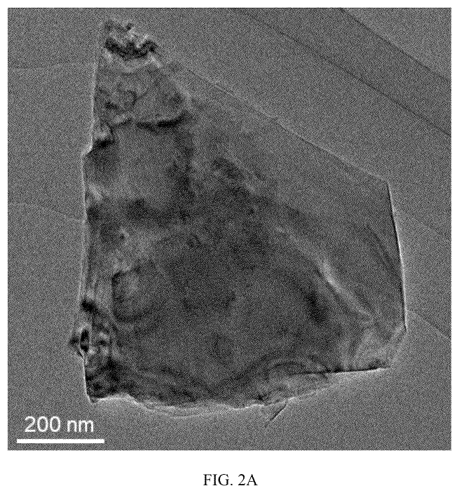

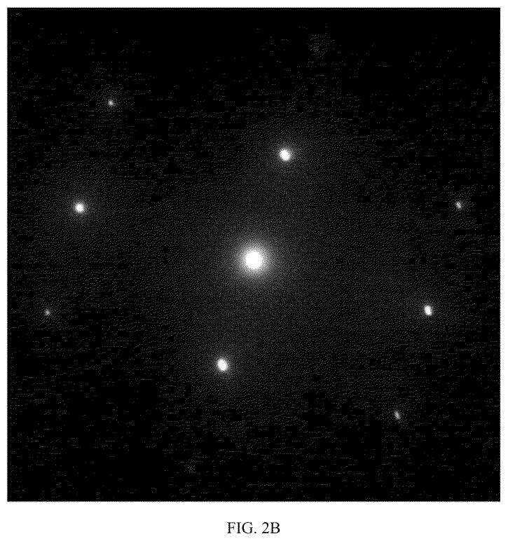

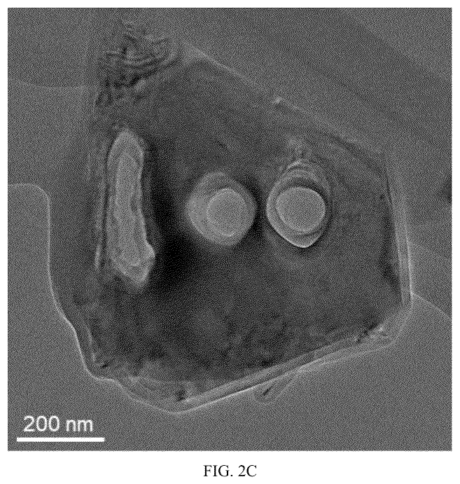

FIG. 2A-FIG. 2C show a comparison diagram of diamond nanosheet before and after etching, in which FIG. 2A shows a diamond nanosheet before etching, FIG. 2B shows the electron diffraction in the <112> direction of diamond (it is indicated that the original sample is diamond), and FIG. 2C shows the diamond nanosheet after etching. In this embodiment, diamond is etched in CO₂ atmosphere with high etching precision and high etching speed.

### Embodiment 2

A diamond sheet obtained by CVD is made into diamond nanosheet, and then the diamond nanosheet is dipped with a 200-mesh copper mesh, and a specimen holder loaded with the copper mesh is put into the ETEM, and H₂ reaction gas (the introduced amount is 5 mbar) is introduced, after that the electron beam is converged to a minimum spot (the diameter is less than 1 nm) and irradiated on the surface of the diamond to be etched, where the Dose value is 15,000 e/nm²s, and the spot is moved by rotating a roller to directionally etch diamond. It takes 45 seconds for diamond to appear a hole first, and 200 nm may be etched in one minute.

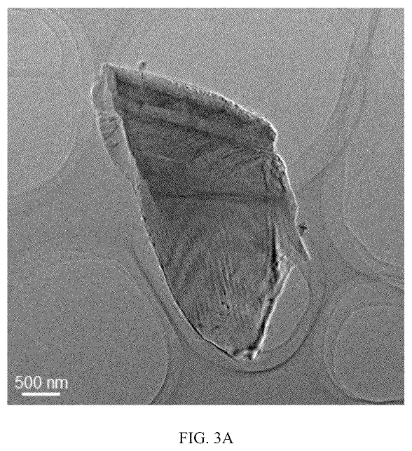

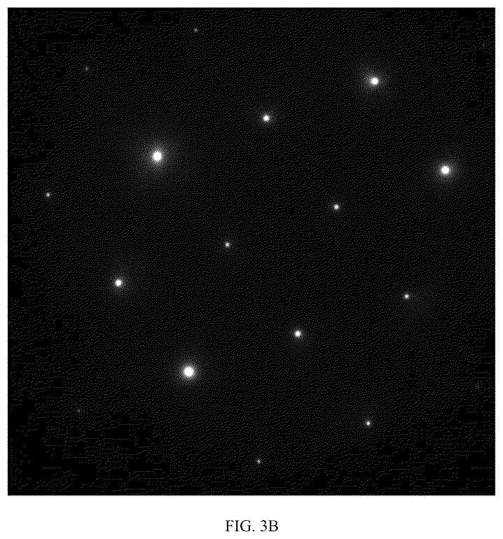

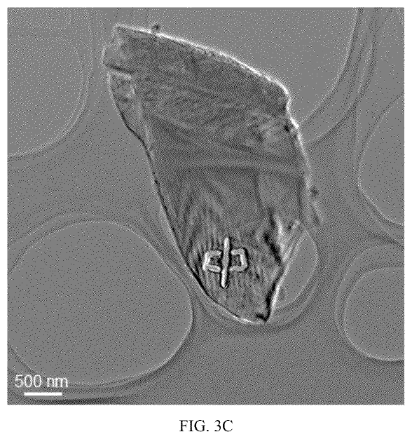

FIG. 3A-FIG. 3C show a comparison diagram of diamond nanosheet before and after etching, in which FIG. 3A is the diamond nanosheet before etching, FIG. 3B shows the electron diffraction in the <110> direction of diamond (it is indicated that the original sample is diamond), and FIG. 3C shows the diamond nanosheet after etching. In this embodiment, diamond is etched in H₂ atmosphere with high etching precision and high etching speed.

### Embodiment 3

A diamond sheet obtained by CVD is made into diamond nanosheet, and then the diamond nanosheet is dipped with a 200-mesh copper mesh, and a prepared diamond nanosheet is put into the ETEM by a specimen holder loaded with the copper mesh, and O₂ reaction gas (the introduced amount is 1 mbar) is introduced, after that the electron beam is converged to a minimum spot (the diameter is less than 1 nm) and irradiated on the surface of the diamond to be etched, where the Dose value is 5,000 e/nm²s, and the spot is moved by rotating a roller to directionally etch diamond. It takes 50 seconds for diamond to appear a hole first, and 150 nm may be etched in one minute.

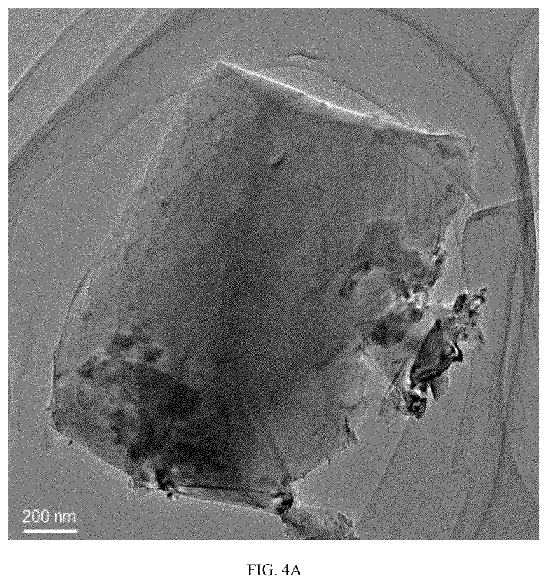

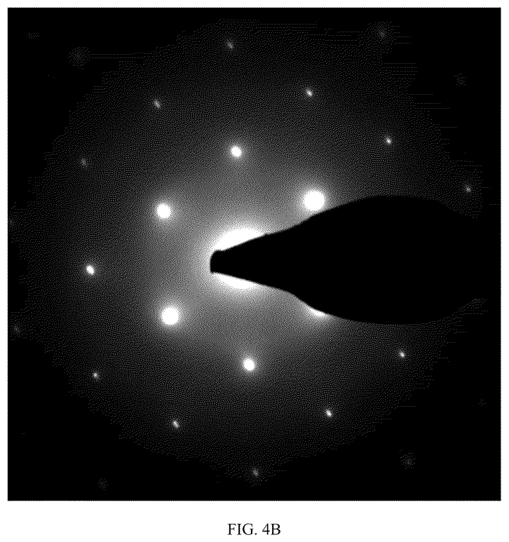

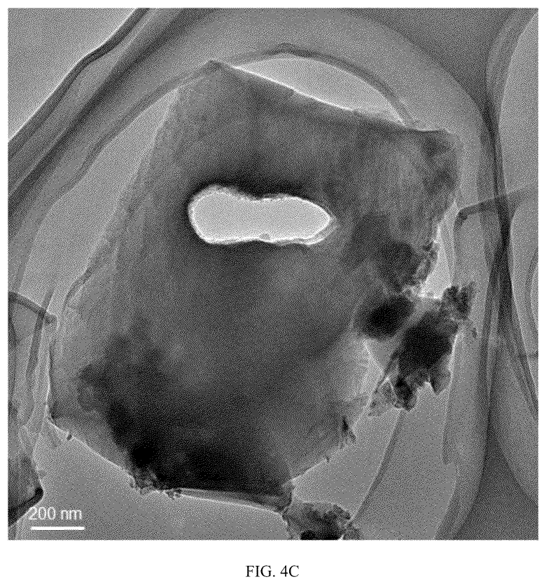

FIG. 4A-FIG. 4C show a comparison diagram of diamond nanosheet before and after etching, in which FIG. 4A is the diamond nanosheet before etching, FIG. 4B shows the electron diffraction in the <110> direction of diamond (it is indicated that the original sample is diamond), and FIG. 4C shows the diamond nanosheet after etching. In this embodiment, diamond is etched in O₂ atmosphere with high etching precision and high etching speed.

### Embodiment 4

A diamond sheet obtained by CVD is made into diamond nanosheet, and then the diamond nanosheet is dipped with a 200-mesh copper mesh, and a specimen holder loaded with the copper mesh is put into the ETEM, and a mixed gas of O₂ and CO₂ (with a volume ratio of 1:1, the introduced amount is 0.1 mbar) is introduced, after that the electron beam is converged to a minimum spot (the diameter is less than 1 nm) and irradiated on the surface of the diamond to be etched, where the Dose value is 20,000 e/nm²s, and the spot is moved by rotating a roller to directionally etch diamond. It takes 20 seconds for diamond to appear a hole first, and 500 nm may be etched in one minute.

### Embodiment 5

A diamond sheet obtained by CVD is made into diamond nanosheet, and then the diamond nanosheet is dipped with a 200-mesh copper mesh, and a specimen holder loaded with the copper mesh is put into the ETEM, and a mixed gas of H₂ and CO₂ (with a volume ratio of 1:1, the introduced amount is 0.1 mbar) is introduced, after that the electron beam is converged to a minimum spot (the diameter is less than 1 nm) and irradiated on the surface of the diamond to be etched, where the Dose value is 20,000 e/nm²s, and the spot is moved by rotating a roller to directionally etch diamond. It takes 30 seconds for diamond to appear a hole first, and 200 nm may be etched in one minute.

### Embodiment 6

A diamond sheet obtained by CVD is made into diamond nanosheet, and then the diamond nanosheet is dipped with a 200-mesh copper mesh, and a specimen holder loaded with the copper mesh is put into the ETEM, and a mixed gas of H₂, CO₂ and H₂O (with a volume ratio of 10:10:1, the introduced amount is 5 mbar) is introduced, after that the electron beam is converged to a minimum spot (the diameter is less than 1 nm) and irradiated on the surface of the diamond to be etched, where the Dose value is 20,000 e/nm²s, and the spot is moved by rotating a roller to directionally etch diamond. It takes 20 seconds for diamond to appear a hole first, and 600 nm may be etched in one minute.

The above-mentioned embodiments only describe the preferred mode of the application, and do not limit the scope of the application. Under the premise of not departing from the design spirit of the application, various modifications and improvements made by ordinary technicians in the field to the technical scheme of the application shall fall within the protection scope defined by the claims of the application.

What is claimed is:

1. A method for in-situ etching diamond, comprising a following step: etching diamond by using
a convergent electron beam in an atmosphere of reaction gas;
wherein the reaction gas is one of CO₂, CO and H₂O;
a pressure of the atmosphere of reaction gas is 0.01-10 mbar,
a temperature of the etching is a room temperature;
a Dose rate value of the convergent electron beam is 5000 e/nm²s to 2×10⁵ e/nm²s.
